(19) United States
(12) Patent Application Publication
(10) Pub. No.: US 2025/0324705 A1
(43) Pub. Date: Oct. 16, 2025

(54) SEMICONDUCTOR STRUCTURE AND METHOD OF FORMING THE SAME

(71) Applicant: HON HAI PRECISION INDUSTRY CO., LTD., New Taipei City (TW)

(72) Inventors: Jheng-Sheng YOU, New Taipei City (TW); Hung-Yu CHEN, New Taipei City (TW); Wen-Yuan HSIEH, New Taipei City (TW)

(21) Appl. No.: 18/675,167

(22) Filed: May 28, 2024

(30) Foreign Application Priority Data
Apr. 10, 2024 (TW) 113113244

(51) Int. Cl. H01L 29/40; H01L 29/20; H01L 29/66; H01L 29/778

(52) U.S. Cl. CPC H10D 64/111; H10D 30/015; H10D 30/475; H10D 62/8503; H10D 64/01

(57) ABSTRACT

A semiconductor structure includes a gate structure on a semiconductor layer on a substrate, a first dielectric layer continuously extending on the gate structure and the semiconductor layer and including a first portion and a second portion, a second dielectric layer on an etch stop layer on at least the first portion of the first dielectric layer, and a field plate including a first field-plate portion on the second dielectric layer and a second field-plate portion on the second portion of the first dielectric layer. Lower surfaces of the first field-plate portion and the second field-plate portion are respectively distanced from the semiconductor layer with a first distance and a second distance that is smaller than the second distance. The field plate and the gate structure respectively have a first projection and a second projection that is not overlapped with the first projection on the substrate.

### CROSS-REFERENCE TO RELATED APPLICATION

This application claims priority to Taiwan Application Serial Number 113113244, filed Apr. 10, 2024, incorporated herein by reference in its entirety.

### BACKGROUND

### Field of Invention

The disclosure relates to a semiconductor structure and a method of forming the same.

### Description of Related Art

Power semiconductor devices continue to develop and are widely used in applications, for example, wireless communications, electronics, and electric vehicles. However, components that can withstand high power should have high breakdown voltages, and better devices should have high electron mobility, good thermal stability, etc. Therefore, a novel semiconductor structure and a method of forming the same are needed to continue to develop the field.

### SUMMARY

The disclosure provides a semiconductor structure including a substrate, a semiconductor layer on the substrate, a gate structure on the semiconductor layer, a first dielectric layer, an etch stop layer, a second dielectric layer, and a field plate. The first dielectric layer extends continuously on the gate structure and the semiconductor layer and includes a first portion and a second portion. The etch stop layer is on at least the first portion of the first dielectric layer. The second dielectric layer is on the etch stop layer. The field plate includes a first field plate portion on the second dielectric layer and a second field plate portion on the second portion of the first dielectric layer, in which a lower surface of the first field plate portion is a first distance away from the semiconductor layer, a lower surface of the second field plate portion is a second distance away from the semiconductor layer, the first distance is larger than the second distance, the field plate has a first projection on the substrate along a vertical direction of the substrate, the gate structure has a second projection on the substrate along the vertical direction of the substrate, and the first projection does not cover the second projection.

The disclosure provides a semiconductor structure including a substrate, a semiconductor layer on the substrate, a gate structure on the semiconductor layer, a first dielectric layer, an etch stop layer, a second dielectric layer, and a field plate. The first dielectric layer extends continuously on the gate structure and the semiconductor layer and includes a first portion, a second portion, and a third portion, in which the third portion is on an upper surface of the gate structure, and the second portion is closer to the third portion than the first portion. The etch stop layer is on at least the first portion of the first dielectric layer. The second dielectric layer is on the etch stop layer. The field plate includes a first field plate portion on the second dielectric layer and a second field plate portion and a third field plate portion respectively on the second portion and the third portion of the first dielectric layer, in which a lower surface of the first field plate portion is a first distance away from the semiconductor layer, a lower surface of the second field plate portion is a second distance away from the semiconductor layer, the first distance is larger than the second distance, the field plate has a first projection on the substrate along a vertical direction of the substrate, the gate structure has a second projection on the substrate along the vertical direction of the substrate, and the first projection covers a portion of the second projection and exposes another portion of the second projection.

The disclosure provides a method of forming a semiconductor structure, including the following operations. A gate structure is formed on a semiconductor layer on a substrate. A first dielectric layer is formed on the gate structure and the semiconductor layer. An etch stop layer is formed on the first dielectric layer. A second dielectric layer is formed on the etch stop layer, in which the etch stop layer separates the second dielectric layer from the first dielectric layer. A portion of the second dielectric layer is etched, in which an etching depth reaches to at least an upper surface of the etch stop layer to form an opening in a remaining portion of the second dielectric layer, and the gate structure is located inside the opening. A field plate is formed on the second dielectric layer and the opening, in which the field plate has a first projection on the substrate along a vertical direction of the substrate, the gate structure has a second projection on the substrate along the vertical direction of the substrate, and the first projection does not cover the second projection or the first projection covers a portion of the second projection and exposes another portion of the second projection.

### BRIEF DESCRIPTION OF THE DRAWINGS

FIGS. 1A to 1C are schematic diagrams of the semiconductor structures according to some embodiments of the disclosure.

FIGS. 2A to 2C are schematic diagrams of the semiconductor structures according to some other embodiments of the disclosure.

FIGS. 3 to 4 are schematic diagrams of the structures during the intermediate stages of forming the semiconductor structure according to some embodiments of the disclosure.

### DETAILED DESCRIPTION

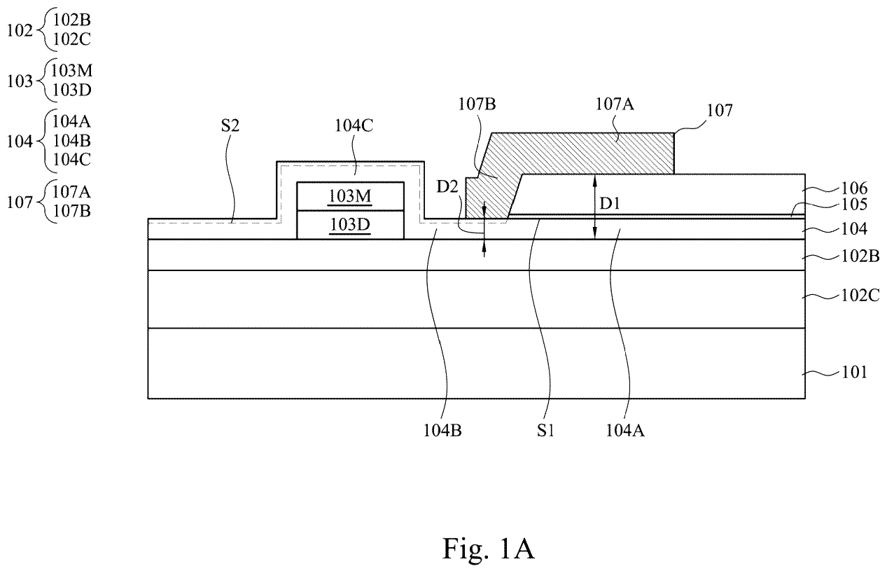

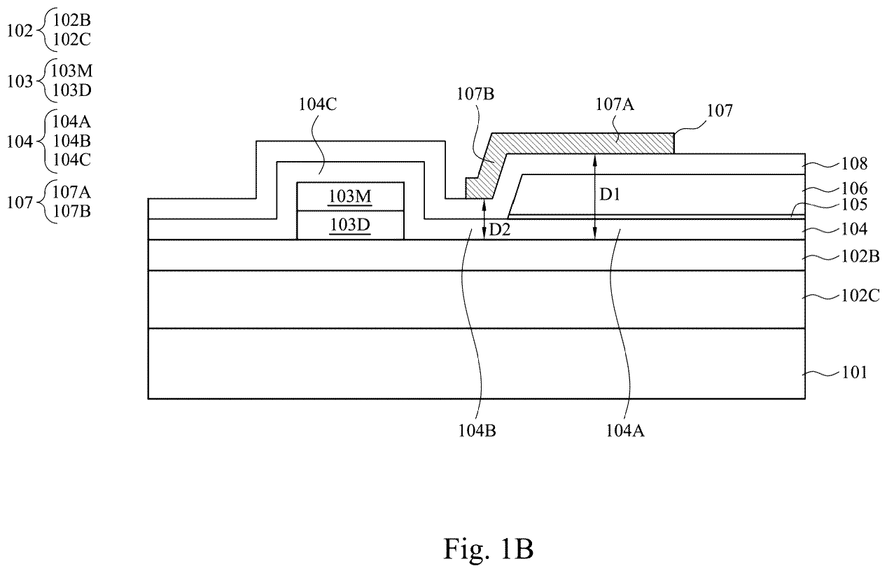

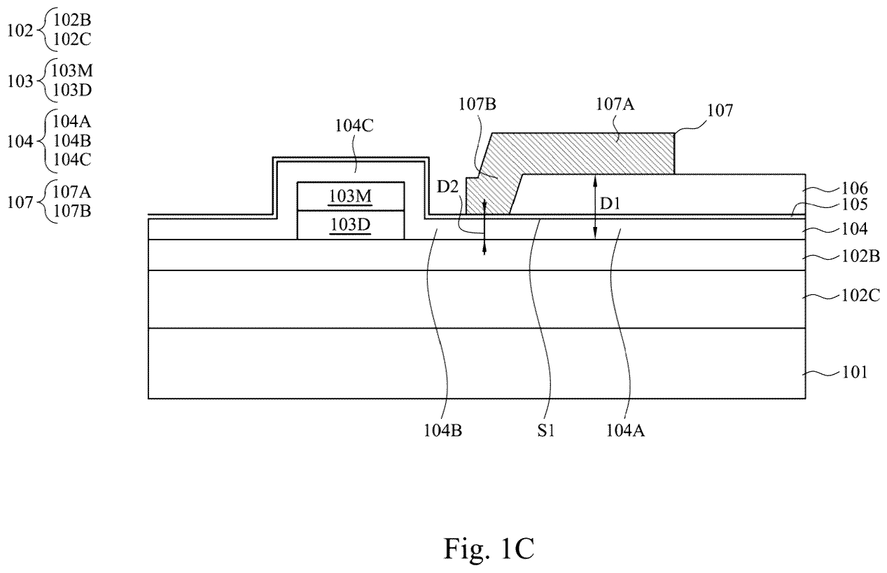

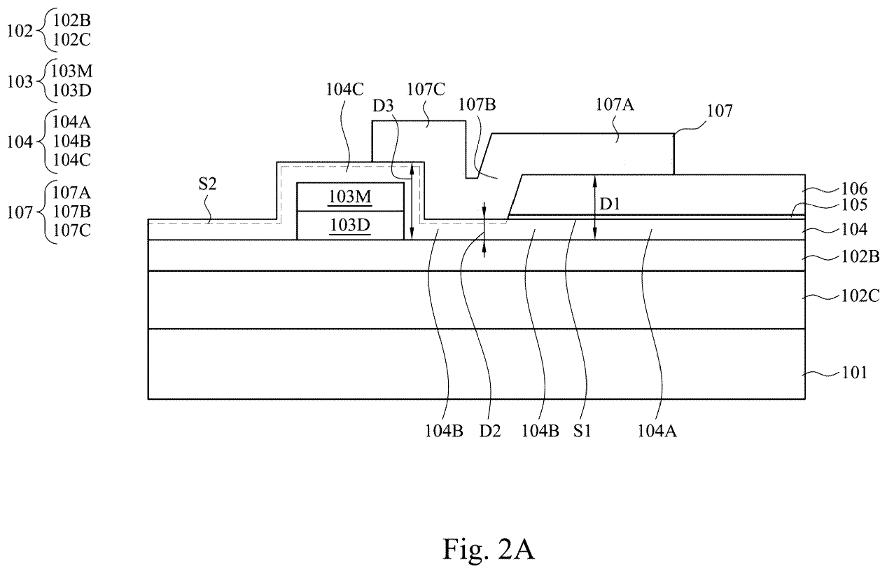

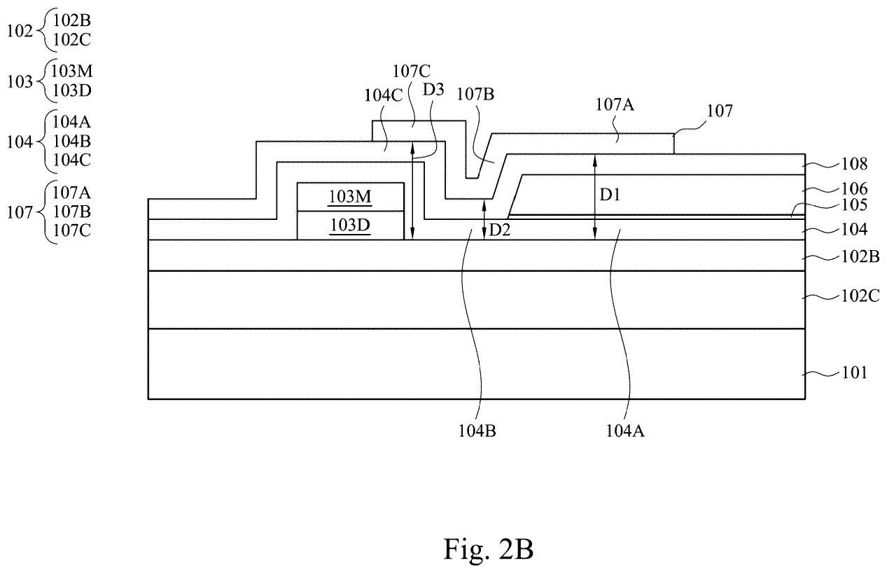

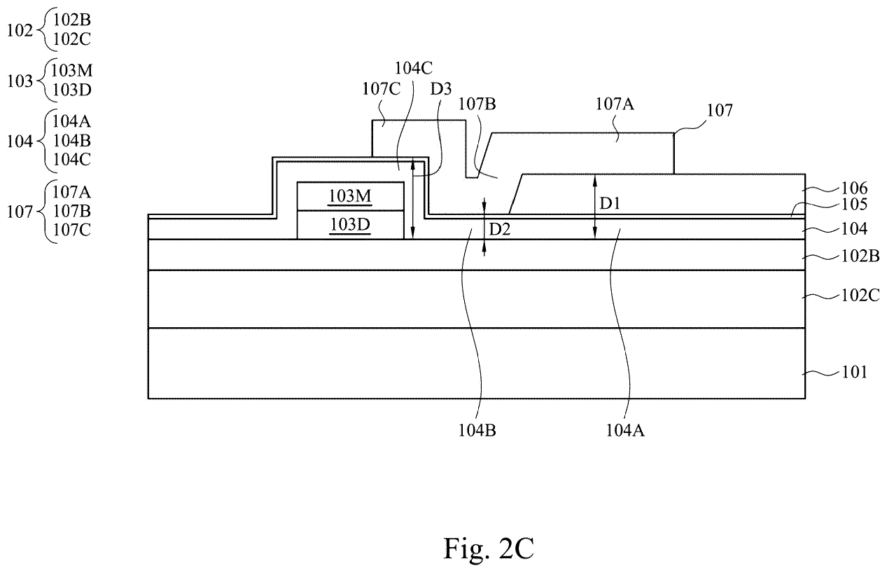

The disclosure provides a semiconductor structure, as shown in FIGS. 1A to 2C, including a substrate 101, a semiconductor layer 102 on the substrate 101, a gate structure 103 on the semiconductor layer 102, a first dielectric layer 104, an etch stop layer 105, a second dielectric layer 106, and a field plate 107. The first dielectric layer 104 extends continuously on the gate structure 103 and the semiconductor layer 102 and includes a first portion 104A, a second portion 104B, and a third portion 104C, in which the third portion 104C is on an upper surface of the gate structure 103, and the second portion 104B is closer to the third portion 104C than the first portion 104A. The etch stop layer 105 is on the first portion 104A and may also be on the second portion 104B and the third portion 104C (or on an remaining portion of the first dielectric layer 104 in addition to the first portion 104A, as shown in FIGS. 1C and 2C). The second dielectric layer 106 is on the etch stop layer 105, in which along a vertical direction of the substrate 101, a projection of the second dielectric layer 106 on the substrate 101 overlaps (or substantially completely overlaps) with a projection of the first portion 104A on the substrate 101 but does not overlap with a projection of the second portion 104B and the third portion 104C on the substrate 101. The field plate 107 includes a first field plate portion 107A on the second dielectric layer 106 on the first portion 104A and a second field plate portion 107B on the second portion 104B, in which a lower surface of the first field plate portion 107A to an upper surface of the semiconductor layer 102 is a first distance D1, a lower surface of the second field plate portion 107B to the upper surface of the semiconductor layer 102 is a second distance D2, and the first distance D1 is larger than the second distance D2. In some embodiments, the first distance D1 is preferably from 500 Å to 5000 Å (e.g., 500 Å, 750 Å, 1000 Å, 2000 Å, 3000 Å, 4000 Å, or 5000 Å), and the second distance D2 is preferably from 200 Å to 5000 Å (e.g., 200 Å, 500 Å, 1000 Å, 1500 Å, 2000 Å, 2500 Å, 3000 Å, or 3500 Å). In some embodiments, the field plate 107 further includes a third field plate portion 107C on the third portion 104C, as shown in FIGS. 2A to 2C. In some embodiments, a lower surface of the third field plate portion 107C to the upper surface of the semiconductor layer 102 is a third distance D3, and the third distance D3 is larger than the second distance D2. In some embodiments, the third distance D3 is preferably from 1800 Å to 6200 Å (e.g., 1800 Å, 2500 Å, 3000 Å, 4000 Å, 5000 Å, or 6200 Å). The field plate 107 of the disclosure makes the semiconductor structure have a high breakdown voltage. In addition, along the vertical direction of the substrate 101, the field plate 107 has a first projection on the substrate 101 and the gate structure 103 has a second projection on the substrate 101. According to an embodiment of the disclosure, the first projection does not cover the second projection (as shown in FIGS. 1A to 1C). According to another embodiment of the disclosure, the first projection covers a portion of the second projection (as shown in FIGS. 2A to 2C). Therefore, the ratio of the gate-source charge (Q_{gs}) between the gate and the source to the gate-drain charge (Q_{gd}) between the gate and the drain can be adjusted by the field plate 107. The figures of the disclosure are simplified without drawing the source and the drain, but the semiconductor structure actually includes the source structure and the drain structure on the semiconductor layer 102, and the gate structure 103 and the field plate 107 are located between the source structure and the drain structure.

The substrate 101 can be any suitable semiconductor substrate and include any suitable semiconductor element, compound, and/or alloy, for example including C, Si, Ge, SiC, BN, AlN, GaN, GaP, GaAs, InP, InAs, InSb, ZnO, SiGe, AlGaAs, InGaAs, InGaP, AlInAs, GaAsP, AlGaN, InGaN, AlGaInP, analogs thereof, or combinations thereof. In some embodiments, although not drawn in the figures, the substrate 101 may also include any suitable active component (e.g., a diode, etc.), passive component (e.g., a resistor, a capacitor, etc.), wire, analogs thereof, or combinations thereof.

The semiconductor layer 102 includes a channel layer 102C and a barrier layer 102B on the channel layer 102C. The channel layer 102C lets carriers flow between the source and the drain. The barrier layer 102B facilitates having a high concentration of the two-dimensional electron gas (2DEG) in the channel layer 102C to have high electron mobility and low resistance. In some embodiments, the channel layer 102C includes epitaxial gallium nitride. In some embodiments, the barrier layer 102B includes AlGaN.

The gate structure 103 controls the flow of carriers in the channel layer 102C. In some embodiments, the gate structure 103 includes a doped layer 103D and a metal layer 103M on the doped layer 103D. The doped layer 103D can be doped with an N-type dopant (e.g., C, Si, Ge, Sn, or analogs thereof) or a P-type dopant (e.g., Be, Mg, Ga, Sr, or analogs thereof) according to the requirements. For example, in some embodiments, the doped layer 103D includes GaN doped with the N-type dopant or the P-type dopant. The metal layer 103M can be any suitable electrode metal.

The first dielectric layer 104 extends continuously on the gate structure 103 and the semiconductor layer 102 to provide insulation. For clarity, the first dielectric layer 104 includes the first portion 104A, the second portion 104B, and the third portion 104C. The first portion 104A overlaps with the second dielectric layer 106 in the vertical direction of the substrate 101. In some embodiments, the first dielectric layer 104 is in direct contact with the semiconductor layer 102 and the gate structure 103. In some embodiments, the first dielectric layer 104 includes SiO₂, Si₃N₄, SiON, or combinations thereof.

The etch stop layer 105 is on the first dielectric layer 104 to control the etching depth more effectively when forming the semiconductor structure. For example, etching can be stopped or paused until reaching the etch stop layer 105 to ensure that the material to be etched is completely removed without remaining a residue and to avoid excessively etching the material under the etch stop layer 105. The etch stop layer 105 helps to avoid unintended residues and/or defects in the semiconductor structure to affect the operation of the semiconductor structure. In some embodiments, the etch stop layers 105 includes AlN, Al₂O₃, SiN, or combinations thereof. In some embodiments, a thickness of the etch stop layer 105 is preferably from 20 Å to 100 Å, e.g., 20 Å, 40 Å, 60 Å, 80 Å, or 100 Å.

The second dielectric layer 106 is on the first portion 104A, does not cover the second portion 104B and the third portion 104C, and is vertically separated from the first dielectric layer 104 by the etch stop layer 105. Since the second dielectric layer 106 does not cover the second portion 104B and the third portion 104C, the first dielectric layer 104 and the second dielectric layer 106 can have a step-like shape. Moreover, since the etch stop layer 105 is between the first dielectric layer 104 and the second dielectric layer 106, when forming the step-like shape of the first dielectric layer 104 and the second dielectric layer 106, etching the second dielectric layer 106 can be stopped or paused at the etch stop layer 105 to obtain the height of the step-like shape being closer to the expectation (refer to the method below for more details). In some embodiments, the second dielectric layer 106 includes SiO₂, Si₃N₄, SiON, or combinations thereof.

The field plate 107 is formed on the step-like shape of the first dielectric layer 104 and the second dielectric layer 106. The field plate 107 redistributes the peak of the electric field of the 2DEG drift region located below the first portion 104A and the second portion 104B and around the gate structure 103, thereby avoiding a breakdown voltage caused by a high peak of the electric field (i.e., the semiconductor structure of the disclosure have a high breakdown voltage). In addition, since the field plate 107 has a step-like shape, the distribution of the electric field around the gate structure 103 is gradually redistributed to more significantly improve the breakdown voltage of the semiconductor structure, so it is unnecessary to increase the distance between the gate structure 103 and the source structure and/or the drain structure to increase the breakdown voltage. In some embodiments, the field plate 107 includes TiN, Ti, AlCu, Al, AlSi, or combinations thereof.

In some embodiments, the field plate 107 extends continuously on the first dielectric layer 104 and the second dielectric layer 106. In some embodiments, the field plate 107 has substantially the same thickness, so an upper surface and a lower surface of the field plate 107 are conformal and/or similar to the step-like shape of the first dielectric layer 104 and the second dielectric layer 106. In some embodiments, the field plate 107 is separated from the gate structure 103 and the semiconductor layer 102 by the first dielectric layer 104. In some embodiments, the lower surface of the first field plate portion 107A is higher than the upper surface of the gate structure 103, and the lower surface of the second field plate portion 107B is lower than the upper surface of the gate structure 103. In some embodiments, the lower surface of the third field plate portion 107C is higher than the upper surface of the gate structure 103. In some embodiments, an upper surface of the second field plate portion 107B is lower than an upper surface of the first field plate portion 107A and in some embodiments, is lower than an upper surface of the third field plate portion 107C. In some embodiments, when the etch stop layer 105 does not cover the remaining portion of the first dielectric layer 104 in addition to the first portion 104A, as shown in FIGS. 1A and 2A, the field plate 107 is in direct contact with the remaining portion of the first dielectric layer 104 (including the second portion 104B and the third portion 104C). In some embodiments, the first field plate portion 107A is further away from the gate structure 103 than the second field plate portion 107B and in some embodiments, is further away from the gate structure 103 than the third field plate portion 107C.

In some embodiments, as shown by the dotted lines of FIGS. 1A and 2A, an upper surface S2 of the second portion 104B and the third portion 104C can be lower than an upper surface S1 of the first portion 104A to adjust the height difference in the field plate 107 on the first dielectric layer 104 and the second dielectric layer 106 more accurately, thereby controlling the distribution of the electric field under the field plate 107 accurately. In these embodiments, the etch stop layer 105 only covers the first portion 104A.

In some embodiments, as shown in FIGS. 1B and 2B, the semiconductor structure may further include a third dielectric layer 108 on the first dielectric layer 104 and the second dielectric layer 106, and the field plate 107 is on the third dielectric layer 108. When the semiconductor structure includes the third dielectric layer 108, the height of the field plate 107 can be adjusted more accurately, thereby controlling the distribution of the electric field under the field plate 107 accurately. In some embodiments, the third dielectric layer 108 continuously covers the first dielectric layer 104 and the second dielectric layer 106 to provide a more continuous and flat surface for the field plate 107 thereon. In some embodiments, the third dielectric layer 108 has substantially the same thickness. In some embodiments, the third dielectric layer 108 is not limited to the number shown in the figures and may include one or more layers. In some embodiments, the third dielectric layer 108 includes a high dielectric constant material (e.g., HfO₂), SiO₂, Si₃N₄, SiON, or combinations thereof.

The disclosure also provides a method of forming the above-mentioned semiconductor structure. The method includes the following operations. The gate structure 103 is formed on the semiconductor layer 102 on the substrate 101. The first dielectric layer 104 is formed on the gate structure 103 and the semiconductor layer 102. The etch stop layer 105 is formed on the first dielectric layer 104. The second dielectric layer 106 is formed on the etch stop layer 105, in which the etch stop layer 105 separates the second dielectric layer 106 from the first dielectric layer 104. A portion of the second dielectric layer 106 is etched with an etching depth at least reaching an upper surface of the etch stop layer 105 to form an opening 1060 in a remaining portion of the second dielectric layer 106, in which the gate structure 103 is in the opening 1060. The field plate 107 is formed on the second dielectric layer 106 and the opening 1060, in which the field plate 107 has the first projection on the substrate 101 along the vertical direction of the substrate 101, the gate structure 103 has the second projection on the substrate 101 along the vertical direction of the substrate 101, and the first projection does not cover the second projection or the first projection covers a portion of the second projection and exposes another portion of the second projection.

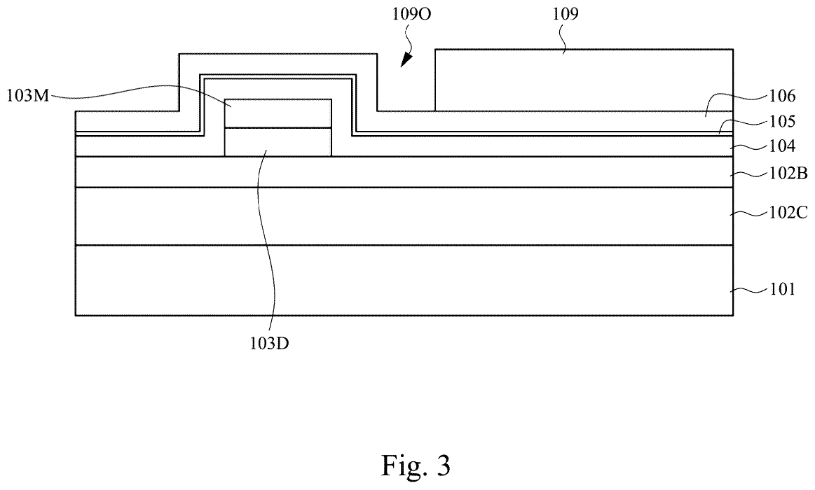

First, refer to FIG. 3. The gate structure 103 is formed on the semiconductor layer 102 on the substrate 101, and the first dielectric layer 104, the etch stop layer 105, and the second dielectric layer 106 are formed on the gate structure 103 and the semiconductor layer 102 sequentially. Forming the gate structure 103, the first dielectric layer 104, the etch stop layer 105, and the second dielectric layer 106 may include any suitable method, e.g., a chemical vapor deposition. In some embodiments, the source structure and the drain structure are formed on the semiconductor layer 102 before forming the first dielectric layer 104, the etch stop layer 105, and the second dielectric layer 106.

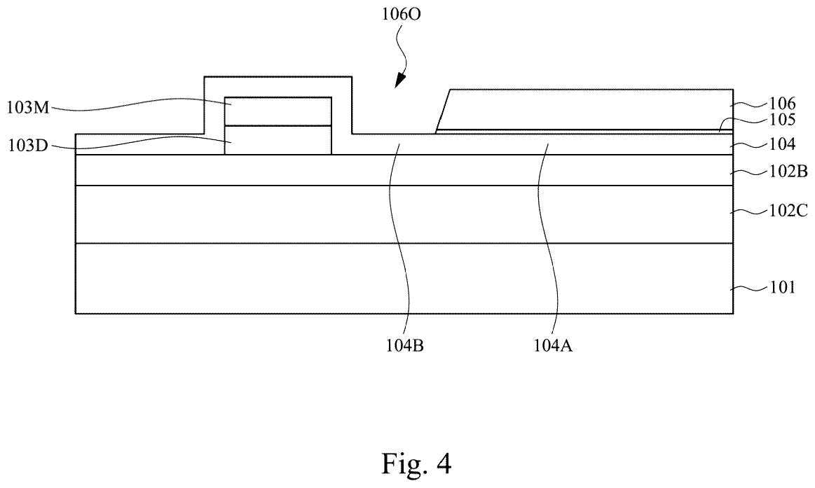

Next, a photoresist layer 109 is formed on the second dielectric layer 106 to be an etch mask to etch the portion of the second dielectric layer 106 to form the second dielectric layer 106 as shown in FIG. 4. The second dielectric layer 106 is patterned by the photoresist layer 109 to form the step-like shape in the first dielectric layer 104 and the patterned second dielectric layer 106, so the field plate 107 can be formed on the step-like shape and has the step-like shape accordingly. In detail, the photoresist layer 109 overlaps with the first portion 104A, and an opening 1090 of the photoresist layer 109 overlaps with the remaining portion (including the second portion 104B and the third portion 104C) of the first dielectric layer 104 in addition to the first portion 104A. The portion of the second dielectric layer 106 exposed by the opening 1090 is etched by any suitable etching method, and the patterned second dielectric layer 106 has an opening 1060 exposing the remaining portion (including the second portion 104B and the third portion 104C) of the first dielectric layer 104 in addition to the first portion 104A. In some embodiments, the suitable etching method includes a wet etching (e.g., using an etchant HF, a buffered oxide etchant (BOE), H₃PO₄, or combinations thereof) or a dry etching (e.g., using etching plasma gas: Cl₂; a combination of HCl and Cl₂; a combination of BCl₃ and SF₆; a combination of S₂F₂ and C₂F₆; C₃F₈; C₄F₈; C₅F₈; a combination of C₄F₆, NF₃, CHF₃, CH₂F₂, CH₃F, SiF₄, C₃F₈ and CCl₂F₂; or combinations thereof). In some embodiments, the etching depth reaches at least the upper surface of the etch stop layer 105 to ensure that the exposed portion of the second dielectric layer 106 are removed completely. The etch stop layer 105 can also prevent the first dielectric layer 104 from being unexpectedly over-etched. In some embodiments, etching can be continued to etch the etch stop layer 105 and remove the etch stop layer 105 in the opening 1060 after the etching is paused when reaching the etch stop layer 105. In some embodiments, after etching the etch stop layer 105 in the opening 1060, the portion (i.e., the remaining portion in addition to the first portion 104A, for example, the second portion 104B and the third portion 104C) of the first dielectric layer 104 below the opening 1060 can also be etched, so the upper surface of the remained lower portion of the second portion 104B in the opening 1060 can be lower than the upper surface of the first portion 104A below the second dielectric layer 106 and outside the opening 1060. In some embodiments, the thickness of the upper portion of the second portion 104B before the etching is preferably from 50 Å to 500 Å (e.g., 50 Å, 100 Å, 200 Å, 300 Å, 400 Å, or 500 Å), and the thickness of the remained lower portion of the second portion 104B after the etching is preferably from 150 Å to 3400 Å (e.g., 150 Å, 500 Å, 1000 Å, 2000 Å, 3000 Å, or 3400 Å). In some embodiments, etching the etch stop layer 105 is performed by a wet etching process (e.g., using a diluted HF, BOE, or a combination thereof), and etching the first dielectric layer 104 is performed by a dry etching process. In some embodiments, etching the etch stop layer 105 and the first dielectric layer 104 is performed by a single continuous wet etching process (e.g., using a diluted HF, BOE, or a combination thereof).

Next, the field plate 107 is formed on the second dielectric layer 106 and the opening 1060 to form the semiconductor structure as shown in FIG. 1A, 1C, 2B, or 2C, or in some embodiments, the third dielectric layer 108 is conformally formed on the second dielectric layer 106 and the opening 1060, and the field plate 107 is formed on the third dielectric layer 108 to form the semiconductor structure as shown in FIG. 1B or 2B. In some embodiments, when the embodiments include forming the third dielectric layer 108, the first dielectric layer 104 is not etched, so the upper surface of the second portion 104B is substantially aligned with the upper surface of the first portion 104A. In some embodiments, forming the field plate 107 includes depositing a field plate material continuously extending on the first dielectric layer 104 and the second dielectric layer 106 and etching an edge portion of the field plate material to form the field plate 107. In some embodiments, the field plate material can be patterned by using another photoresist layer (not drawn) formed on the field plate material as a mask to form the field plate 107 shown in FIGS. 1A to 2C.

The semiconductor structure of the disclosure and the semiconductor structure formed by the method of the disclosure have a high breakdown voltage to reduce current leakage. Moreover, the semiconductor structure has high electron mobility and good thermal stability. The semiconductor structure can be used not only for high electron mobility transistors (HEMTs) but also for high-power semiconductor components. The step-like shape of the first dielectric layer and the second dielectric layer formed by using the etch stop layer between the first dielectric layer and the second dielectric layer makes the height of the step-like shape closer to the expectation without an unexpected etching residue remained on the step-like shape, so the field plate has more desirable height difference along the step-like shape to significantly increase the breakdown voltage and adjust the charge distribution accurately. The height difference in the step-like shape of the field plate can also be adjusted in detail by adding the third dielectric layer or by etching an upper portion of a portion of the first dielectric layer. The continuously extending field plate having the height difference can be formed by a single patterned process, thereby simplifying the process, improving the efficiency, and avoiding the damage to the field plate compared with forming the field plate in multiple steps.

What is claimed is:

1. A semiconductor structure, comprising:
a substrate;
a semiconductor layer on the substrate;
a gate structure on the semiconductor layer;
a first dielectric layer continuously extending on the gate structure and the semiconductor layer, wherein the first dielectric layer comprises a first portion and a second portion;
an etch stop layer on at least the first portion of the first dielectric layer;
a second dielectric layer on the etch stop layer; and
a field plate comprising a first field plate portion on the second dielectric layer and a second field plate portion on the second portion of the first dielectric layer, wherein a lower surface of the first field plate portion is a first distance away from the semiconductor layer, a lower surface of the second field plate portion is a second distance away from the semiconductor layer, the first distance is larger than the second distance, the field plate has a first projection on the substrate along a vertical direction of the substrate, the gate structure has a second projection on the substrate along the vertical direction of the substrate, and the first projection does not cover the second projection.

2. The semiconductor structure of claim 1, wherein the field plate extends continuously on the first dielectric layer and the second dielectric layer.

3. The semiconductor structure of claim 1, further comprising a third dielectric layer on the first dielectric layer and the second dielectric layer, wherein the field plate is on the third dielectric layer.

4. The semiconductor structure of claim 1, wherein an upper surface of the second portion of the first dielectric layer is lower than an upper surface of the first portion of the first dielectric layer.

5. A semiconductor structure, comprising:
a substrate;
a semiconductor layer on the substrate;
a gate structure on the semiconductor layer;
a first dielectric layer continuously extending on the gate structure and the semiconductor layer, wherein the first dielectric layer comprises a first portion, a second portion, and a third portion, the third portion is on an upper surface of the gate structure, and the second portion is closer to the third portion than the first portion;
an etch stop layer on at least the first portion of the first dielectric layer;
a second dielectric layer on the etch stop layer; and
a field plate comprising a first field plate portion on the second dielectric layer and a second field plate portion and a third field plate portion respectively on the second portion and the third portion of the first dielectric layer, wherein a lower surface of the first field plate portion is a first distance away from the semiconductor layer, a lower surface of the second field plate portion is a second distance away from the semiconductor layer, the first distance is larger than the second distance, the field plate has a first projection on the substrate along a vertical direction of the substrate, the gate structure has a second projection on the substrate along the vertical direction of the substrate, and the first projection covers a portion of the second projection and exposes another portion of the second projection.

6. The semiconductor structure of claim 5, wherein along the vertical direction of the substrate, a projection of the second dielectric layer on the substrate overlaps with a projection of the first portion of the first dielectric layer on the substrate and the projection of the second dielectric layer on the substrate does not overlap with a projection of the second portion and the third portion of the first dielectric layer on the substrate.

7. The semiconductor structure of claim 5, wherein a lower surface of the third field plate portion is a third distance away from the semiconductor layer, and the third distance is larger than the second distance.

8. A method of forming a semiconductor structure, comprising:
forming a gate structure on a semiconductor layer on a substrate;
forming a first dielectric layer on the gate structure and the semiconductor layer;
forming an etch stop layer on the first dielectric layer;
forming a second dielectric layer on the etch stop layer, wherein the etch stop layer separates the second dielectric layer from the first dielectric layer;
etching a portion of the second dielectric layer, wherein an etching depth reaches to at least an upper surface of the etch stop layer to form an opening in a remaining portion of the second dielectric layer, and the gate structure is located inside the opening; and
forming a field plate on the second dielectric layer and the opening, wherein the field plate has a first projection on the substrate along a vertical direction of the substrate, the gate structure has a second projection on the substrate along the vertical direction of the substrate, and the first projection does not cover the second projection or the first projection covers a portion of the second projection and exposes another portion of the second projection.

9. The method of claim 8, further comprising etching a portion of the first dielectric layer below the opening to make an upper surface of the portion of the first dielectric layer below the opening is lower than an upper surface of a portion of the first dielectric layer below the second dielectric layer.

10. The method of claim 8, further comprising conformally forming a third dielectric layer on the second dielectric layer and the opening before forming the field plate.
